(19) United States
(12) Patent Application Publication
(10) Pub. No.: US 2023/0120390 A1
(43) Pub. Date: Apr. 20, 2023

(54) DISPLAY PANEL AND FABRICATION METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Zhan SHI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/963,510

(22) PCT Filed: Jun. 24, 2020
(86) PCT No.: PCT/CN2020/097928

§ 371 Date: Jul. 21, 2020

(30) Foreign Application Priority Data
May 15, 2020 (CN) 202010413221.7

(51) Int. Cl. H10K 59/122; H10K 50/84; H10K 71/00; H10K 50/81; H10K 50/82

(52) U.S. Cl. CPC H01L 27/3246; H01L 51/5237; H01L 51/56; H01L 51/5206; H01L 51/5221; H01L 2227/32

(57) ABSTRACT

A display panel and a fabrication method thereof are provided. The display panel includes an array substrate, a light-emitting device layer disposed on the array substrate, and an encapsulation layer disposed on the light-emitting device layer. The light-emitting device layer includes a pixel definition layer disposed on the array substrate, and the pixel definition layer includes a plurality of grooves formed along a periphery of a sub-pixel area of the display panel, and at least one of the grooves corresponds to the sub-pixel area.

### FIELD OF INVENTION

The present application relates to a field of display technology, and more particularly to a display panel and a fabrication method thereof.

### BACKGROUND

In display technology, organic light-emitting diode (OLED) displays have many advantages such as lightness and thinness, active light-emissions, fast response times, wide viewing angles, wide color gamut, high brightness, and low power consumption, and have gradually become a third-generation display technology following liquid crystal display (LCD).

In existing OLED display panels, since a pixel definition layer is generally composed of organic substances, such that the pixel definition layer has properties such as oxygen affinity and hydrophilicity, a large amount of moisture and oxygen exist in the pixel definition layer of the existing OLED display panels. With operations of OLED display panels, the moisture and oxygen in the pixel definition layer may corrode the pixel definition layer, anode layer, or light-emitting material layer, reducing a lifespan of the OLED display panels.

Therefore, a display panel is urgently needed to solve above technical problems.

### Technical Problem

The present application provides a display panel and a fabrication method thereof to solve the technical problem of short lifespan of existing OLED display panels.

### Technical Solution

The present application provides a display panel, comprising an array substrate, a light-emitting device layer disposed on the array substrate, and an encapsulation layer disposed on the light-emitting device layer, wherein the light-emitting device layer comprises a pixel definition layer disposed on the array substrate, and

wherein the pixel definition layer comprises a plurality of grooves formed along a periphery of a sub-pixel area of the display panel, and at least one of the grooves corresponds to the sub-pixel area.

In a display panel of the present application, any one of the grooves comprises at least one sub-groove, and the sub-grooves are formed continuously or discontinuously along the periphery of the sub-pixel area.

In a display panel of the present application, an opening of any one of the grooves faces the sub-pixel area corresponding to the groove, and

wherein a depth of the groove between two adjacent sub-pixel areas gradually increases to gradually decreases, and the depth of the groove corresponding to a center area between two adjacent sub-pixel areas is the greatest.

In a display panel of the present application, any two adjacent grooves are connected by a first through hole.

In a display panel of the present application, the light-emitting device layer further comprises an anode layer disposed in a same layer as the pixel definition layer and a light-emitting layer disposed on the anode layer,

wherein a maximum distance between the light-emitting layer and the array substrate is less than a minimum distance between the groove and the array substrate, and the groove is filled with a material of the light-emitting layer.

In a display panel of the present application, the light-emitting device layer further comprises a cathode layer covering the pixel definition layer and the light-emitting layer in the light-emitting device layer, and

wherein the grooves are filled with a material of the cathode layer.

The present application further provides a fabrication method of a display panel, comprising:

forming a pixel definition layer on an array substrate;

forming a plurality of first openings and at least one groove along the first openings on the pixel definition layer by using a photomask process;

performing a heating treatment to the pixel definition layer;

filling a light-emitting material in the first opening to form a light-emitting layer of the display panel; and

forming a cathode layer on the light-emitting layer and the pixel definition layer so that the cathode layer covers the light-emitting layer and the pixel definition layer.

In a fabrication method of a display panel of the present application, wherein the step of forming the plurality of first openings and at least one groove along the first openings on the pixel definition layer using the photomask process comprises:

forming a plurality of first openings on the pixel definition layer by using a first photomask process; and

forming the at least one groove along the first openings on the pixel definition layer by using a second photomask process;

or

simultaneously forming the plurality of first openings and the at least one groove along the first openings on the pixel definition layer by using a first photomask process,

wherein the at least one groove comprises at least one sub-groove, and the sub-groove is formed continuously or discontinuously along the periphery of the sub-pixel area.

In a display panel of the present application, wherein the step of filling the first opening with the light-emitting material to form the light-emitting layer of the display panel comprises:

filling the first opening and the groove with the light-emitting material so that the light-emitting material disposed in the first opening forms the light-emitting layer of the display panel and the light-emitting material located in the groove is formed as a compensation layer,

wherein the light-emitting material in the first opening and the light-emitting material in the groove are disposed discontinuously.

In a display panel of the present application, an opening of any one of the grooves faces the sub-pixel area corresponding to the groove, and

wherein a depth of the groove gradually increases to gradually decreases, and the depth of the groove corresponding to a center area between two adjacent sub-pixel areas 200 is the greatest.

In a display panel of the present application, any two adjacent grooves are connected by a first through hole.

In a display panel of the present application, a maximum distance between the light-emitting layer and the array substrate is less than a minimum distance between the groove and the array substrate, and the groove is filled with a material of the light-emitting layer.

In a display panel of the present application, the groove is filled with a material of the cathode layer.

The present application further provides a display panel having a backlight module and a display panel on the backlight module, wherein the display panel comprises an array substrate, a light-emitting device layer disposed on the array substrate, and an encapsulation layer disposed on the light-emitting device layer, wherein the light-emitting device layer comprises a pixel definition layer disposed on the array substrate, and

wherein the pixel definition layer comprises a plurality of grooves formed along a periphery of a sub-pixel area of the display panel, and at least one of the grooves corresponds to the sub-pixel area.

In a display panel of the present application, any one of the grooves comprises at least one sub-groove, and the sub-grooves are formed continuously or discontinuously along the periphery of the sub-pixel area.

In a display panel of the present application, an opening of any one of the grooves faces the sub-pixel area corresponding to the groove, and

wherein a depth of the groove between two adjacent sub-pixel areas gradually increases to gradually decreases, and the depth of the groove corresponding to a center area between two adjacent sub-pixel areas is the greatest.

In a display panel of the present application, any two adjacent grooves are connected by a first through hole.

In a display panel of the present application, the light-emitting device layer further comprises an anode layer disposed in a same layer as the pixel definition layer and a light-emitting layer disposed on the anode layer,

wherein a maximum distance between the light-emitting layer and the array substrate is less than a minimum distance between the groove and the array substrate, and the groove is filled with a material of the light-emitting layer.

In a display panel of the present application, the light-emitting device layer further comprises a cathode layer covering the pixel definition layer and the light-emitting layer in the light-emitting device layer, and

wherein the grooves are filled with a material of the cathode layer.

### Advantageous Effects

The present application forms at least one groove around a sub-pixel area on a pixel definition layer, and the groove increases a diffusion path of the pixel definition layer, so that the moisture and oxygen in the pixel definition layer can diffuse from a channel formed by the groove and the moisture and oxygen in the pixel definition layer are thus removed, thereby increasing a lifespan of an OLED display panel.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic structural diagram of a display panel of the present application.

FIG. 2 is a first top view of the display panel of the present application.

FIG. 3 is a second top view of the display panel of the present application.

FIG. 4 is a first cross-sectional view of the display panel of the present application.

FIG. 5 is a second cross-sectional view of the display panel of the present application.

FIG. 6 is a third cross-sectional view of the display panel of the present application.

FIG. 7 is a flow chart of a fabrication method of the display panel of the present application.

### DETAILED DESCRIPTION

In order to make the purpose, technical solutions and effects of the present application clearer and clearer, the present application will be described in further detail below with reference to the accompanying drawings and examples. It should be understood that specific embodiments described herein are only used to explain the present application and are not used to limit the present application.

In existing OLED display panels, since a pixel definition layer is generally composed of organic substances, so that the pixel definition layer has properties such as oxygen affinity and hydrophilicity, a large amount of moisture and oxygen exist in the pixel definition layer of the existing OLED display panels. With operations of OLED display panels, the moisture and oxygen located in the pixel definition layer may corrode the pixel definition layer, anode layer, or light-emitting material layer, reducing a lifespan of the OLED display panels. The present application provides following technical solutions based on the above technical issues.

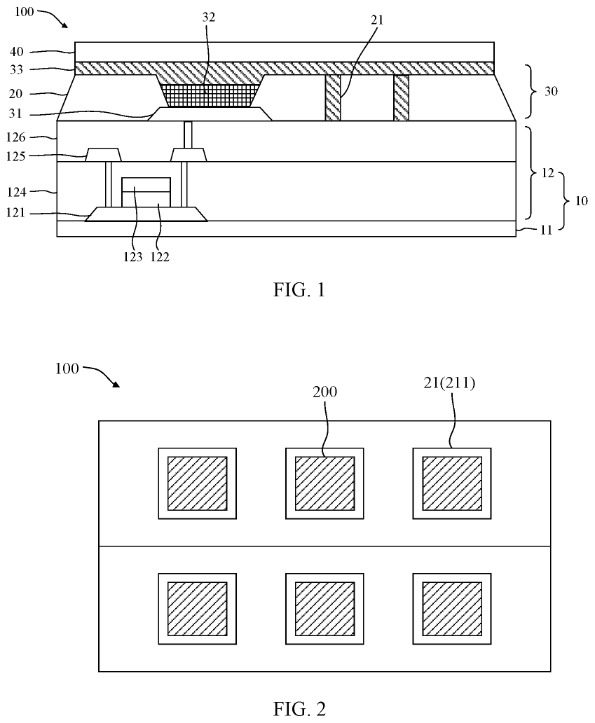

Referring to FIGS. 1-5, the present application provides a display panel 100, which comprises an array substrate 10, a light-emitting device layer 30 disposed on the array substrate 10, and an encapsulation layer 40 disposed on the light-emitting device layer 30. The light-emitting device layer 30 comprises a pixel definition layer 20 disposed on the array substrate 10.

Herein, the pixel definition layer 20 comprises a groove 21 formed along a periphery of a sub-pixel area 200 of the display panel 100, and the at least one groove 21 corresponds to the sub-pixel area 200.

The present application forms the at least one groove 21 around the sub-pixel area 200 on the pixel definition layer 20, and the groove 21 increases a diffusion path of the pixel definition layer 20 so that moisture and oxygen in the pixel definition layer 20 can diffuse from a channel formed by the groove 21 and the moisture and oxygen in the pixel definition layer 20 are thus removed, thereby increasing a lifespan of the OLED display panel 100.

Technical solutions of the present application will now be described in conjunction with specific embodiments.

Referring to FIG. 1, the array substrate 10 comprises a first substrate 11 and a driving circuit layer 12 disposed on the first substrate 11. The first substrate 11 may be a rigid substrate or a flexible substrate. When the first substrate 11 is the rigid substrate, a material of the first substrate 11 may be glass, quartz, or the like. When the first substrate 11 is the flexible substrate, a material of the first substrate 11 may be, for example, polyimide. In the OLED display panel 100, a substrate structure is generally formed of the flexible substrate, which will not be described in detail here.

The driving circuit layer 12 comprises a plurality of thin film transistors. The thin film transistors may be structures of an etch-barrier type, a back-channel etching type, or a top-gate thin film transistor type, which is not specifically limited. For example, a thin film transistor of the top-gate thin film transistor type structure may comprise an active layer 121 disposed on the first substrate 11, a gate insulating layer 122 disposed on the active layer 121, a gate insulating layer 122 disposed on a gate layer 123, an interlayer insulating layer 124 disposed on the gate layer 123, source/drain layers 125 disposed on the interlayer insulating layer 124, and a planarization layer 126 disposed on the source/drain layers 125.

Referring to FIG. 1, the light-emitting device layer 30 comprises a pixel definition layer 20 disposed on the array substrate 10, an anode layer 31 disposed on a same layer as the pixel definition layer 20, a light-emitting layer 32 disposed on the anode layer 31, and a cathode layer 33 disposed on the light-emitting layer 32.

In this embodiment, the pixel definition layer 20, the anode layer 31, the light-emitting layer 32, and the cathode layer 33 are all conventional structures in the prior art, and will not be described in detail in the present application.

The pixel definition layer 20 comprises a first opening 22. The light-emitting layer 32 is disposed in the first opening 22 or the light-emitting layer 32 is disposed in the first opening 22 and on the pixel definition layer 20 corresponding to both sides of the first opening 22, and will not be described in detail in the present application.

In this embodiment, the encapsulation layer 40 may be a thin-film encapsulation layer or a hard cover plate. The above two structures are conventional structures in the prior art and are not specifically limited in this application.

In this embodiment, the pixel definition layer 20 further comprises a plurality of grooves 21.

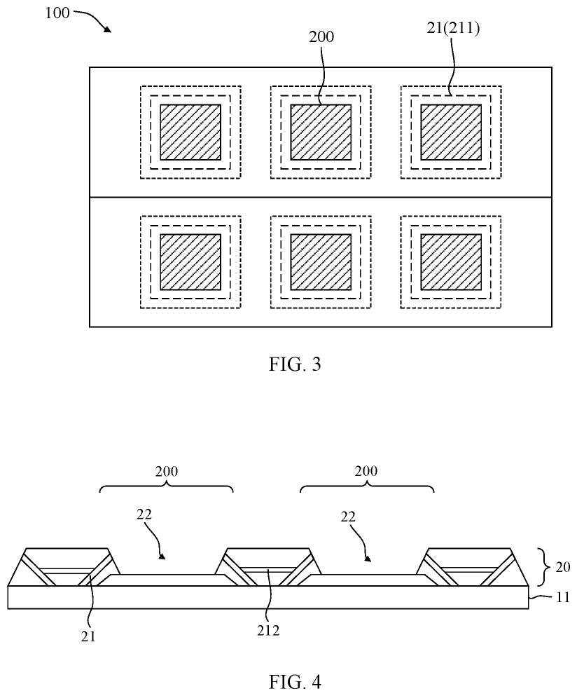

Referring to FIG. 2, in a top view, any one of the sub-pixel areas 200 comprises a groove 21 defined along the periphery of the sub-pixel area 200. Alternatively, referring to FIG. 3, in the top view, any one of the sub-pixel areas 200 comprises two grooves 21 defined along the periphery of the sub-pixel area 200.

In this embodiment, any one of the grooves 21 comprises at least one sub-groove 211. Referring to FIG. 2, the sub-groove 211 is continuously defined along the periphery of the sub-pixel area 200. Referring to FIG. 3, the sub-grooves 211 are discontinuously defined along the periphery of the sub-pixel area 200. Alternatively, the sub-groove 211 is a through hole having a predetermined diameter, and a plurality of through holes are defined along the periphery of the sub-pixel area 200.

In this embodiment, by providing a plurality of grooves 21 on the pixel definition layer 20, the pixel definition layer 20 is in a fluffy state, and residual moisture and oxygen in the pixel definition layer 20 can diffuse from the groove 21 in subsequent processes such as a heating process like curing of the pixel definition layer 20, thereby preventing corrosions of the anode layer 31 or the light-emitting layer 32 caused by the moisture and oxygen in the OLED display panel 100 during operations, which improves a lifespan of the OLED display panel 100.

Please refer to FIG. 4, the opening of any one of the grooves 21 faces the sub-pixel area 200 corresponding to the groove 21. The opening of the groove 21 faces the sub-pixel so that a depth of the groove 21 can be further increased under the same vertical distance, and a diffusion channel for the moisture and oxygen in the pixel definition layer 20 is increased.

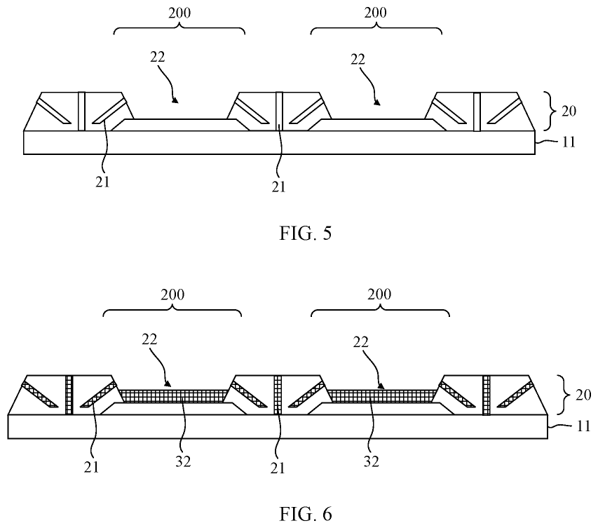

Referring to FIG. 5, between two adjacent sub-pixel areas 200, a depth of the groove 21 gradually increases to gradually decreases, and the depth of the groove 21a corresponding to a center area between two adjacent sub-pixel areas 200 is the greatest. In this embodiment, a groove 21 with a maximum depth is formed in the pixel definition layer 20 far from the sub-pixel area 200, which prevents the pixel definition layer 20 from being unable to divide the sub-pixel areas 200 well due to the presence of the groove 21. That is, the light-emitting material may deform the pixel definition layer 20 due to compression. Therefore, the depth of the groove 21 of the present application near the sub-pixel areas 200 is lesser.

Referring to FIG. 4, two adjacent grooves 21 are connected through a first through hole 212. The first through hole 212 is formed between two adjacent grooves 21 to increase the connection between the grooves 21, that is the diffusion path of moisture and oxygen in the pixel definition layer 20 is increased.

Referring to FIG. 6, any one of the grooves 21 is filled with the material of the light-emitting layer 32.

In this embodiment, a maximum distance between the light-emitting layer 32 and the array substrate 10 is less than a minimum distance between the groove 21 and the array substrate 10, and the light-emitting material in the first opening 22 and the light-emitting material in the grooves 21 are disposed discontinuously.

Since the light-emitting material is a hydrophilic organic material, during fabrication processes, the light-emitting material can fill into the pixel definition layer 20 in an evaporation process to absorb the moisture and oxygen in the pixel definition layer 20, thereby preventing the moisture and oxygen in the pixel definition layer 20 from reacting with the light-emitting material in the first opening 22 or in the anode layer 31, which causes irreversible changes. Technical solutions of this embodiment may not require additional processes to prevent the moisture and oxygen in the pixel definition layer 20 from entering the sub-pixel area 200.

In addition, considering the cost of the light-emitting material, the light-emitting material filling the groove 21 can be replaced by other materials with strong moisture absorption and oxygen absorption, but it adds an additional process. Therefore, manufacturers can consider specific plans based on actual costs, and this application does not make specific limitations.

Referring to FIG. 1, the groove 21 may also be filled with a material of the cathode layer 33.

A presence of the groove 21 in the present application removes the moisture and oxygen in the pixel definition layer 20 by using a heating process, and the presence of the groove 21 may cause unevenness of a light emitting device in subsequent processes. Herein, when the cathode layer 33 is formed in the present application, the cathode layer 33 is filled in the groove 21 to achieve a smooth surface of the light-emitting device layer 30.

In the technical solutions of this embodiment, the cathode layer 33 in the groove 21 can be regarded as a plurality of resisting units that are individually disposed, which are arranged in parallel with the cathode layer 33 to actually reduce an impedance of the cathode layer 33 and ensure voltage uniformity of the cathode layer 33, thereby improving display uniformity of the display panel 100.

In this application, by providing at least one groove 21 around the sub-pixel area 200 on the pixel definition layer 20, the groove 21 increases the diffusion path of the pixel definition layer 20, so that the moisture and oxygen in the pixel definition layer 20 can be removed from the channel by diffusing out of the groove 21, removing moisture and oxygen in the pixel definition layer 20, thereby increasing a lifespan of the OLED display panel 100.

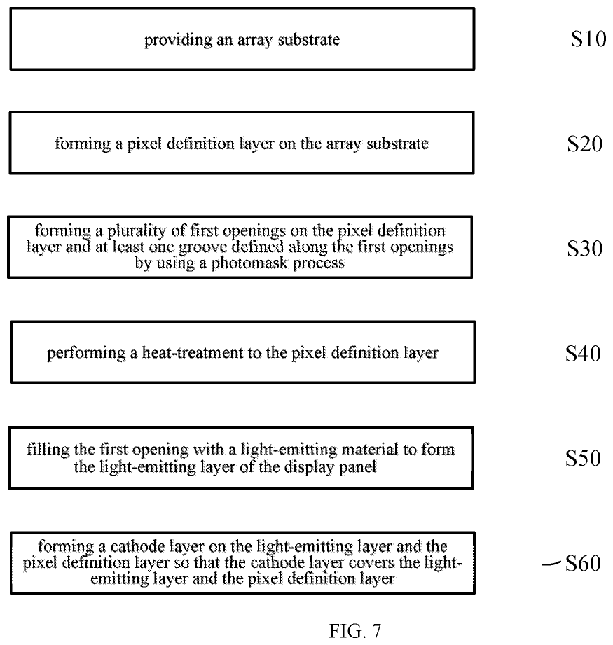

Referring to FIG. 7, the present application also provides a fabrication method of the display panel 100, which comprises:

S10: providing an array substrate 10.

Referring to FIG. 1, the array substrate 10 comprises a first substrate 11 and a driving circuit layer 12 disposed on the first substrate 11. The first substrate 11 may be a rigid substrate or a flexible substrate. When the first substrate 11 is the rigid substrate, a material of the first substrate 11 may be glass, quartz, or the like. When the first substrate 11 is the flexible substrate, a material of the first substrate 11 may be, for example, polyimide. In the OLED display panel 100, a substrate structure is generally formed of the flexible substrate, which will not be described in detail here.

The driving circuit layer 12 comprises a plurality of thin film transistors. The thin film transistors may be structures of an etch-barrier type, a back-channel etching type, or a top-gate thin film transistor type, which is not specifically limited. For example, a thin film transistor of the top-gate thin film transistor type structure may comprise an active layer 121 disposed on the first substrate 11, a gate insulating layer 122 disposed on the active layer 121, a gate insulating layer 122 disposed on a gate layer 123, an interlayer insulating layer 124 disposed on the gate layer 123, source/drain layers 125 disposed on the interlayer insulating layer 124, and a planarization layer 126 disposed on the source/drain layers 125.

S20: forming a pixel definition layer 20 on the array substrate 10.

S30: forming a plurality of first openings 22 on the pixel definition layer 20 and at least one groove 21 defined along the first openings 22 by using a photomask process.

In this embodiment, the step S30 may specifically comprise:

S301: forming the plurality of first openings 22 on the pixel definition layer 20 by using a first photomask process; and

S302: forming the at least one groove 21 defined along the first opening 22 on the pixel definition layer 20 by using a second photomask process.

Alternatively, the plurality of first openings 22 and the at least one groove 21 defined along the first opening 22 are simultaneously formed on the pixel definition layer 20 by using the first photomask process.

In this embodiment, please refer to FIG. 2, in a top view, any one of the sub-pixel areas 200 comprises a groove 21 defined along the periphery of the sub-pixel area 200. Alternatively, referring to FIG. 3, in the top view, any one of the sub-pixel areas 200 comprises two grooves 21 defined along the periphery of the sub-pixel area 200.

In this embodiment, any one of the grooves 21 comprises at least one sub-groove 211. Referring to FIG. 2, the sub-groove 211 is continuously defined along the periphery of the sub-pixel area 200. Referring to FIG. 3, the sub-grooves 211 are discontinuously defined along the periphery of the sub-pixel area 200. Alternatively, the sub-groove 211 is a through hole having a predetermined diameter, and a plurality of through holes are defined along the periphery of the sub-pixel area 200.

S40: performing a heat-treatment to the pixel definition layer 20.

In the above embodiment, the present application defines the groove 21 in the pixel definition layer 20 for the main purpose of allowing moisture and oxygen in the pixel definition layer 20 to diffuse from the groove 21 in subsequent heating process of the pixel definition layer 20, thereby preventing corrosions of the anode layer 31 or the light-emitting layer 32 caused by the moisture and oxygen in the OLED display panel 100 during operations, which improves a lifespan of the OLED display panel 100.

S50: filling the first opening 22 with a light-emitting material to form the light-emitting layer 32 of the display panel 100

In this embodiment, step S50 may specifically comprise:

filling the first opening 22 and the groove 21 with the light-emitting material, so that the light-emitting material disposed in the first opening 22 forms the light-emitting layer 32 of the display panel 100 and the light-emitting material disposed in the groove 21 forms a compensation layer; and

wherein the light-emitting material in the first opening 22 and the light-emitting material in the groove 21 are disposed discontinuously.

Since the light-emitting material is a hydrophilic organic material, during fabrication processes, the light-emitting material can fill into the pixel definition layer 20 in an evaporation process to absorb the moisture and oxygen in the pixel definition layer 20, thereby preventing the moisture and oxygen in the pixel definition layer 20 from reacting with the light-emitting material in the first opening 22 or in the anode layer 31, which causes irreversible changes. Technical solutions of this embodiment may not require additional processes to prevent the moisture and oxygen in the pixel definition layer 20 from entering the sub-pixel area 200.

In addition, considering the cost of the light-emitting material, the light-emitting material filling the groove 21 can be replaced by other materials with strong moisture absorption and oxygen absorption, but it adds an additional process. Therefore, manufacturers can consider specific plans based on actual costs, and this application does not make specific limitations.

S60: forming a cathode layer 33 on the light-emitting layer 32 and the pixel definition layer 20 so that the cathode layer 33 covers the light-emitting layer 32 and the pixel definition layer 20.

A presence of the groove 21 in the present application removes the moisture and oxygen in the pixel definition layer 20 by using a heating process, and the presence of the groove 21 may cause unevenness of a light emitting device in the subsequent processes. Herein, when the cathode layer 33 is formed in the present application, the cathode layer 33 is filled in the groove 21 to achieve a smooth surface of the light-emitting device layer 30.

In the technical solutions of this embodiment, the cathode layer 33 in the groove 21 can be regarded as a plurality of resisting units that are individually disposed, which are arranged in parallel with the cathode layer 33 to actually reduce an impedance of the cathode layer 33 and ensure voltage uniformity of the cathode layer 33, thereby improving display uniformity of the display panel 100.

In this application, by providing at least one groove 21 around the sub-pixel area 200 on the pixel definition layer 20, the groove 21 increases the diffusion path of the pixel definition layer 20, so that the moisture and oxygen in the pixel definition layer 20 can be removed from the channel by diffusing out of the groove 21, removing moisture and oxygen in the pixel definition layer 20, thereby increasing a lifespan of the OLED display panel 100.

In this embodiment, any two adjacent grooves 21 are connected by a first through hole 212.

For a specific structure of the above embodiments, please refer to FIGS. 5-6, and no more details will be given here.

The present application also proposes a display device, wherein the display device has a backlight module and the above-mentioned display panel disposed on the backlight module. The working principle of the display device in this embodiment is the same as or similar to the working principle of the above-mentioned display panel, which will not be repeated here.

The present application provides a display panel and a fabrication method thereof. The display panel comprises an array substrate, a light-emitting device layer disposed on the array substrate, and an encapsulation layer disposed on the light-emitting device layer, wherein the light-emitting device layer comprises a pixel definition layer disposed on the array substrate. The pixel definition layer comprises a plurality of grooves formed along a periphery of a sub-pixel area of the display panel, and at least one of the grooves corresponds to the sub-pixel area. The present application forms at least one groove around a sub-pixel area on a pixel definition layer, and the groove increases a diffusion path of the pixel definition layer, so that the moisture and oxygen in the pixel definition layer can diffuse from a channel formed by the groove and the water and oxygen in the pixel definition layer are thus removed, thereby increasing a lifespan of the OLED display panel.

The descriptions of the above embodiments are only used to help understand the technology of the present application, solutions and their core ideas; those of ordinary skill in the art should understand that they can still modify the technical solutions described in the foregoing embodiments or equivalently replace some of the technical features, and these modifications or replacements do not make the essence of the corresponding technical solutions deviate from the scope of the technical solutions of the embodiments of the present application.

1. A display panel, comprising:
an array substrate;
a light-emitting device layer disposed on the array substrate; and
an encapsulation layer disposed on the light-emitting device layer, wherein the light-emitting device layer comprises a pixel definition layer disposed on the array substrate, and
wherein the pixel definition layer comprises a plurality of grooves formed along a periphery of a sub-pixel area of the display panel, and at least one of the grooves corresponds to the sub-pixel area.

2. The display panel according to claim 1, wherein any one of the grooves comprises at least one sub-groove, and the sub-grooves are formed continuously or discontinuously along the periphery of the sub-pixel area.

3. The display panel according to claim 1, wherein an opening of any one of the grooves faces the sub-pixel area corresponding to the groove, and
wherein a depth of the groove between two adjacent sub-pixel areas gradually increases to gradually decreases, and the depth of the groove corresponding to a center area between two adjacent sub-pixel areas is the greatest.

4. The display panel of claim 3, wherein any two adjacent grooves are connected by a first through hole.

5. The display panel according to claim 3, wherein the light-emitting device layer further comprises an anode layer disposed in a same layer as the pixel definition layer and a light-emitting layer disposed on the anode layer,
wherein a maximum distance between the light-emitting layer and the array substrate is less than a minimum distance between the groove and the array substrate, and the groove is filled with a material of the light-emitting layer.

6. The display panel according to claim 1, wherein the light-emitting device layer further comprises a cathode layer covering the pixel definition layer and the light-emitting layer in the light-emitting device layer, and
wherein the grooves are filled with a material of the cathode layer.

7. A fabrication method of a display panel, comprising following steps:
forming a pixel definition layer on an array substrate;
forming a plurality of first openings and at least one groove along the first openings on the pixel definition layer by using a photomask process;
performing a heating treatment to the pixel definition layer;
filling a light-emitting material in the first opening to form a light-emitting layer of the display panel; and
forming a cathode layer on the light-emitting layer and the pixel definition layer so that the cathode layer covers the light-emitting layer and the pixel definition layer.

8. The fabrication method according to claim 7, wherein the step of forming the plurality of first openings and the at least one groove along the first openings on the pixel definition layer using the photomask process comprises:
forming the plurality of first openings on the pixel definition layer by using a first photomask process; and
forming the at least one groove along the first openings on the pixel definition layer by using a second photomask process;
or
simultaneously forming the plurality of first openings and the at least one groove along the first openings on the pixel definition layer by using the first photomask process,
wherein the at least one groove comprises at least one sub-groove, and the sub-groove is formed continuously or discontinuously along a periphery of a sub-pixel area.

9. The fabrication method according to claim 7, wherein the step of filling the first openings with the light-emitting material to form the light-emitting layer of the display panel comprises:
filling the first openings and the groove with the light-emitting material so that the light-emitting material disposed in the first openings forms the light-emitting layer of the display panel and the light-emitting material located in the groove is formed as a compensation layer,
wherein the light-emitting material in the first openings and the light-emitting material in the groove are disposed discontinuously.

10. The fabrication method according to claim 7, wherein an opening of any one of the grooves faces the sub-pixel area corresponding to the groove, and
wherein a depth of the groove gradually increases to gradually decreases, and the depth of the groove corresponding to a center area between two adjacent sub-pixel areas 200 is the greatest.

11. The fabrication method according to claim 10, wherein any two adjacent grooves are connected by a first through hole.

12. The fabrication method according to claim 10, wherein a maximum distance between the light-emitting layer and the array substrate is less than a minimum distance between the groove and the array substrate, and the groove is filled with a material of the light-emitting layer.

13. The fabrication method according to claim 7, wherein the groove is filled with a material of the cathode layer.

14. A display device having a backlight module and a display panel on the backlight module, wherein the display panel comprises:
an array substrate;
a light-emitting device layer disposed on the array substrate; and
an encapsulation layer disposed on the light-emitting device layer, wherein the light-emitting device layer comprises a pixel definition layer disposed on the array substrate, and
wherein the pixel definition layer comprises a plurality of grooves formed along a periphery of a sub-pixel area of the display panel, and at least one of the grooves corresponds to the sub-pixel area.

15. The display device according to claim 14,
wherein any one of the grooves comprises at least one sub-groove, and the sub-grooves are formed continuously or discontinuously along the periphery of the sub-pixel area.

16. The display device according to claim 14, wherein an opening of any one of the grooves faces the sub-pixel area corresponding to the groove, and
wherein a depth of the groove between two adjacent sub-pixel areas gradually increases to gradually decreases, and the depth of the groove corresponding to a center area between two adjacent sub-pixel areas is the greatest.

17. The display device of claim 16, wherein any two adjacent grooves are connected by a first through hole.

18. The display device according to claim 16, wherein the light-emitting device layer further comprises an anode layer disposed in a same layer as the pixel definition layer and a light-emitting layer disposed on the anode layer,
wherein a maximum distance between the light-emitting layer and the array substrate is less than a minimum distance between the groove and the array substrate, and the groove is filled with a material of the light-emitting layer.

19. The display device according to claim 14, wherein the light-emitting device layer further comprises a cathode layer covering the pixel definition layer and the light-emitting layer in the light-emitting device layer, and
wherein the grooves are filled with a material of the cathode layer.
